(19) United States
(12) Patent Application Publication
(10) Pub. No.: US 2015/0090180 A1
(43) Pub. Date: Apr. 2, 2015

(54) Epitaxial growth of compound semiconductors using lattice-tuned domain-matching epitaxy

(71) Applicant: Ultratech, Inc., San Jose, CA (US)

(72) Inventors: Andrew M. Hawryluk, Los Altos, CA (US); Daniel Stearns, Los Altos Hills, CA (US)

(73) Assignee: Ultratech, Inc., San Jose, CA (US)

(21) Appl. No.: 14/040,326

(22) Filed: Sep. 27, 2013

(51) Int. Cl. C30B 25/18; C30B 25/06; C30B 29/10; C30B 23/02; C30B 29/40

(52) U.S. Cl. CPC C30B 25/183; C30B 23/025; C30B 29/40; C30B 29/10; C30B 25/06
USPC 117/89; 117/105; 204/192.1

(57) ABSTRACT

A method of epitaxially growing a final film using a crystalline substrate wherein the final film cannot be grown directly on the substrate surface is disclosed. The method includes forming a transition layer on the upper surface of the substrate. The transition layer has a lattice spacing that varies between its lower and upper surfaces. The lattice spacing at the lower surface matches the lattice spacing of the substrate to within a first lattice mismatch of 7%. The lattice spacing at the upper surface matches the lattice spacing of the final film to within a second lattice mismatch of 7%. The method also includes forming the final film on the upper surface of the transition layer.

### FIELD

The present disclosure relates to the epitaxial growth of compound semiconductors, and in particular relates to such growth using lattice-tuned domain-matching epitaxy.

### BACKGROUND

There is a strong market incentive to develop processes for forming device-grade, heteroepitaxial films of different semiconductor compounds on Si wafers. Materials of interest include the intermetallic compound SiC, and certain continuous alloy series, such as SiₓGe₁₋ₓ, AlₓGa₁₋ₓN, GaₓAl₁₋ₓAs, InₓGa₁₋ₓAs, InₓGa₁₋ₓP, and InₓAl₁₋ₓAs. Other materials of interest include optoelectronic compounds, such as ZnO. The driving economic interest is that these materials often have superior electrical and opto-electronic properties than conventional silicon. Applications for these materials range from high-power transistors and switches to high electron mobility transistors, laser diodes, solar cells, and detectors.

Unfortunately, unlike Si, these materials cannot be brought into mass production because it is currently impossible to grow these materials in large crystalline boules that can then be processes to form large (e.g., 300 mm) crystalline wafers. Therefore, it is currently impossible to take advantage of the economic scaling and cost reductions that have been developed over the years for silicon devices made from crystalline silicon wafers.

Accordingly, there is a need for methods of growing single-crystal compound semiconductors on Si wafers, and then using these as substrate to form more complex heterostructures. Such methods would allow for manufacturing superior electronic and opto-electronic devices at relatively low cost.

### SUMMARY

An aspect of the disclosure is a method of epitaxially growing a final film using a crystalline substrate wherein the final film cannot, for all practical purposes, be grown directly on the substrate surface. The method includes forming a transition layer on the substrate surface. The transition layer has a lattice spacing that varies between its lower and upper surfaces. The lattice spacing at the lower surface matches the substrate lattice spacing to within a first lattice mismatch of 7%. The lattice spacing at the upper surface matches the lattice spacing of the final film to within a second lattice mismatch of 7%. The method also includes forming the final film on the upper surface of the transition layer. In various embodiments of the method, the first and second lattice mismatches can be 2%, or 1% or substantially 0%.

Another aspect of the disclosure is a method of epitaxially growing a desired (final) film having a lattice spacing a_{F} using a crystalline substrate having an upper surface and a lattice spacing aₛ. The method includes: forming on the upper surface of the substrate at least one transition layer having a lower surface, an upper surface, a thickness h, and a lattice spacing a_{T}(z) that varies between the lower and upper surfaces such that the lattice spacing a_{T}(0) at the lower surface satisfies m·a_{T}(0)=n·aₛ to within a first lattice mismatch of 7%, where n, m are integers, and the lattice spacing a_{T}(h) at the upper surface satisfies the relationship i·a_{T}(h)=j·a_{F} to within a second lattice mismatch of within 7%, where i, j are integers; and forming the desired film on the upper surface of the transition layer. In various embodiments of the method, the first and second lattice mismatches can be 2%, or 1% or substantially 0%.

Another aspect of the disclosure is a method of forming a template substrate for growing a desired film having a lattice spacing a_{F}. The method includes: forming on an upper surface of a crystalline substrate having a lattice spacing aₛ at least one transition layer having a lower surface, an upper surface, a thickness h, and a lattice spacing a_{T}(z) that varies between the lower and upper surfaces of the at least one transition layer such that the lattice spacing a_{T}(0) at the lower surface satisfies the relationship m·a_{T}(0)=n·aₛ to within a first lattice mismatch of 7%, where n, m are integers, and the lattice spacing a_{T}(h) at the upper surface of the at least one transition layer satisfies the relationship i·a_{T}(h)=j·a_{F} to within a second lattice mismatch of 7%, where i, j are integers. In various embodiments of the method, the first and second lattice mismatches can be 2%, or 1% or substantially 0%.

Additional features and advantages will be set forth in the Detailed Description that follows, and in part will be readily apparent to those skilled in the art from the description or recognized by practicing the embodiments as described in the written description and claims hereof, as well as the appended drawings. It is to be understood that both the foregoing general description and the following Detailed Description are merely exemplary, and are intended to provide an overview or framework to understand the nature and character of the claims.

### BRIEF DESCRIPTION OF THE DRAWINGS

The accompanying drawings are included to provide a further understanding, and are incorporated in and constitute a part of this specification. The drawings illustrate one or more embodiment(s), and together with the Detailed Description serve to explain principles and operation of the various embodiments. As such, the disclosure will become more fully understood from the following Detailed Description, taken in conjunction with the accompanying Figures, in which:

FIG. 1 is a cross-sectional view of an example semiconductor substrate;

FIG. 2A is a cross-sectional view of the substrate of FIG. 1 in the process of forming an epitaxial film on the semiconductor substrate of FIG. 1;

FIG. 2B shows the resulting film formed on the substrate by the epitaxial deposition process of FIG. 2.

FIG. 3 is a plot of the in-plane lattice spacing “a” (Å) and DME ratios (vertical axis) versus material composition;

FIG. 4A shows the transition layer being formed using lattice-tuned domain matching epitaxy (LT-DME), and also shows the transition layer being optionally laser processed during the LT-DME process;

FIG. 4B is a cross-sectional view of an example template substrate formed from the substrate of FIG. 1 and that includes a transition layer having a variable lattice spacing, and also shows the transition layer being optionally laser processed with a laser beam;

FIG. 4C is a close-up view of the transition layer of thickness h as formed on the substrate surface using LT-DME as illustrated in FIG. 4B, and illustrates how the lattice spacing a_{T}(z) varies through the transition layer from z=0 to z=h;

FIG. 4D is an idealized plot of the lattice spacing a_{T}(z) of the transition layer of FIG. 4C, illustrating one example of how the lattice spacing varies linearly through the transition layer in a manner corresponding to the variation in the material composition of the material layers that form the transition layer;

FIG. 4E is a cross-sectional view of an example template substrate that includes the starting substrate and p transition layers formed thereon;

FIG. 4F is a cross-sectional view similar to FIG. 4E and that shows a final film layer formed on the uppermost transition layer of the template substrate;

FIG. 5A is a cross-sectional view of an example template substrate that include a starting substrate and a transition layer, and that shows the final film layer being formed atop the transition layer using a domain-matching epitaxy (DME) processes;

FIG. 5B is similar to FIG. 5A and shows the resulting structure of the process shown in FIG. 5A;

FIG. 6 is a flow diagram of an example method of forming a desired final film on a template substrate using a starting substrate on which the desired film cannot be directly formed;

FIG. 7 is a cross-sectional view of an example template substrate that includes a starting substrate and seven transition layers; and

FIG. 8 is a flow diagram of another example method of forming a desired film on a template substrate using a starting substrate on which the desired film cannot be directly formed.

### DETAILED DESCRIPTION

Reference is now made in detail to various embodiments of the disclosure, examples of which are illustrated in the accompanying drawings. Whenever possible, the same or like reference numbers and symbols are used throughout the drawings to refer to the same or like parts. The drawings are not necessarily to scale, and one skilled in the art will recognize where the drawings have been simplified to illustrate the key aspects of the disclosure.

The claims as set forth below are incorporated into and constitute part of this Detailed Description.

The entire disclosure of any publication or patent document mentioned herein is incorporated by reference.

Cartesian coordinates may be shown in some of the Figures for the sake of reference and such coordinates are not intended to be limiting as to direction or orientation.

In the discussion below, the parameter “a” is used to generally denote the lattice spacing or lattice constant of material, i.e., the distance between the unit cells of a crystalline structure of the material, which is also the spacing between atoms or species that make up a unit cell. The parameter aₛ denotes the lattice spacing of a substrate. The parameter a_{T}(z) denotes the variable (e.g., graded) lattice spacing of a transition layer; The parameter a_{F} denotes the lattice spacing of a final film formed on the uppermost transition layer.

Also in the discussion below, m and n are integers, as are i and j.

The acronym DME as used below stands for “Domain-Matching Epitaxy,” while the acronym LT-DME stands for “Lattice-Tuned Domain-Matching Epitaxy.”

In the discussion below, the term “within X %” means “equal to or less than X %.”

An aspect of the disclosure is directed to growing single-crystal compounds on a Si substrate. However, this aspect of the disclosure should not be interpreted as limiting the disclosure to Si substrates only. Reference to Si substrates in the description herein is solely by way of illustration that relates to cost-effective manufacturing. In cases where manufacturing cost is less of an issue, other crystalline substrates can be utilized, including but not limited to, Ge, SiC, Al₂O₃, GaN, diamond and others. The methods described herein work equally well for non-silicon crystalline substrates.

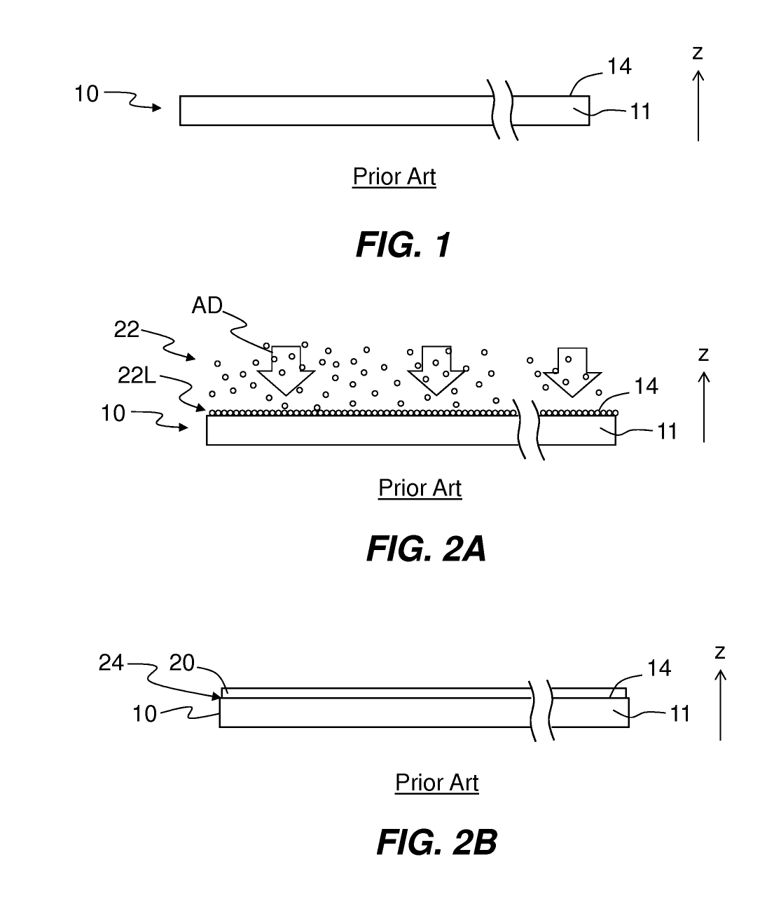

FIG. 1 is cross-sectional view of a crystalline semiconductor substrate (“substrate”) 10 that has a body 11 and an upper surface 14. In an example, substrate 10 is Si wafer, which has a cubic (tetragonal) crystal structure with a (1,1,1) orientation and a lattice spacing aₛ of 3.84 angstroms (Å). In the discussion below, substrate 10 is referred to as Si wafer 10 in connection with various example embodiments. Substrate 10 is also referred to herein as the “starting substrate” in connection with forming a template substrate, as described in greater detail below.

Substrate 10 can be used to grow a device-grade heteroepitaxial film 20 via a prior art deposition processes of a material (species) 22, as schematically illustrated in FIGS. 2A and 2B. Arrows AD in FIG. 2A show the direction of deposition of species 22. Film 20 and substrate surface 12 define a substrate-film interface 24. FIG. 2A shows a single layer (“heterolayer”) 22L of species 22 at substrate surface 12. Film 20 consists of a plurality of heterolayers 22L.

There are two main challenges in developing methods for forming (i.e., depositing or growing) device-grade heteroepitaxial films 20 of compound semiconductors on substrates 10. The first is that there must be a thermodynamic driving force to cause the layers 22L of deposited film 20 to grow commensurately with the single-crystal template of substrate 10. This is typically achieved by making the in-plane crystal structures isomorphic and by matching the lattice spacings of the substrate and film so that there is a high degree of registration across the film-substrate interface 24. The second challenge is to manage the problem of thermal expansion. Heteroepitaxial growth typically requires high temperature to promote surface mobility and achieve long-range order. If the coefficient of thermal expansion of substrate 10 and material 22 is not matched, then there will be large residual thermal stresses in the cooled film 20 that can produce deformation and cracking.

Heteroepitaxial growth involves competition between the surface energies of the substrate 10 and film 20, and the energy at substrate-film interface 24. This competition gives rise to three possible growth modes for film 20. The Frank-Van der Merwe (FM) growth mode is observed when the interfacial energy dominates and film 20 grows conformally layer-by-layer. The Stranski-Krastanov (SK) growth mode is layer-by-layer up to a critical thickness where the film 20 begins to form a 3D morphology consisting of a network of islands. Finally, in the Volmer-Weber (VW) growth mode, the islands are formed directly on Si wafer surface 12. The SK and VW growth modes cause the heterolayers to break up into small domains with a high density of grain boundaries.

A key to growing a high-quality heteroepitaxial film 20 is to find conditions that favor the FM mode. The challenge is to engineer the substrate-film interface 24 so that the layer growth is commensurate with the underlying crystalline template of substrate 10. In particular, there must be some degree of registration between the lattices of substrate 10 and the growing film 20. A requirement for this condition is that the crystallographic planes of substrate 10 and film 20 have the same symmetry.

The crystal structures of example semiconductor materials of interest are listed in Table 1, below.

TABLE 1

| | | Lattice spacing | Crystalline |
|---|---|---|---|
| Material | Orientation | “a” (Å) | structure |
| Si | (111) | 3.84 | cubic (tetragonal) |
| Ge | (111) | 4.00 | cubic (tetragonal) |
| 3C—SiC | (111) | 3.06 | cubic (zincblende) |
| AlₓGa₁₋ₓAs | (111) | 4.00-4.00 (x = 0 − 1) | cubic (zincblende) |
| GaₓAl₁₋ₓN | (001) | 3.11-3.19 (x = 0 − 1) | hcp (wurtzite) |
| lnₓGa₁₋ₓAs | (111) | 4.00-4.28 (x = 0 − 1) | cubic (zincblende) |
| lnₓGa₁₋ₓP | (111) | 3.85-4.15 (x = 0 − 1) | cubic (zincblende) |
| lnₓAl₁₋ₓAs | (111) | 4.00-4.28 (x = 0 − 1) | cubic (zincblende) |
| ZnO | (001) | 3.252 | hcp (wurtzite) |

It can be seen that the Ga—Al—N compounds have the hexagonal close-pack (hcp) (Wurtzite) structure. These films invariably grow in the (001) orientation, where the in-plane lattice has an hcp configuration. If these films are to be grown heteroepitaxially, then the substrate used must match the hexagonal symmetry. All of the other materials (Si, Ge, SiC, GaAlAs, InGaAs, InGaP, InAlAs) have a cubic crystalline structure and the hexagonal symmetry is obtained in the (111) orientation. Hence, all of the materials in Table 1 have matching in-plane symmetries in the given orientation.

While film 20 can be deposited by a number of different techniques (e.g., PVD, CVD, evaporation, sputtering, and atomic layer deposition (ALD)), the ALD process is advantageous because it is constrained to provide FM growth.

For typical deposition processes, controlling the energy of the deposited species 22 is important to control the energy at the interfaces between the different layers during the deposition process. Too little energy and the deposited material 22 cannot re-align with the crystallographic direction of the underlying substrate 10. In ALD, the energetics of the deposition process can be controlled by controlling the temperature of substrate 10 during deposition, or by performing laser spike annealing during or after the deposition process. The short-range order is defined by the chemical reactions. Long rang order is defined by the inclusion of additional energy, which can be supplied by elevated temperatures or by laser annealing. By using laser spike annealing, the time and magnitude of energy directed to and absorbed by thin film 20 can be well controlled. This provides unique, independent control of both the deposited material 22 and its energetics. While laser-assisted ALD (LA-ALD) is just one deposition process that can be employed, it provides unprecedented control of the growth interface and allows for low temperature (<400° C.) deposition. This mitigates the problems associated with different thermal expansion coefficients for materials deposited onto substrates 10 at higher temperatures.

The other standard requirement for heteroepitaxial growth of film 20 is that there should be a match in the lattice spacing (or lattice constant) “a”. Ideally this would correspond to a one-to-one registration of species 22 across the substrate-film interface 24 that serves to “lock” the heterolayer 22L onto substrate surface 12.

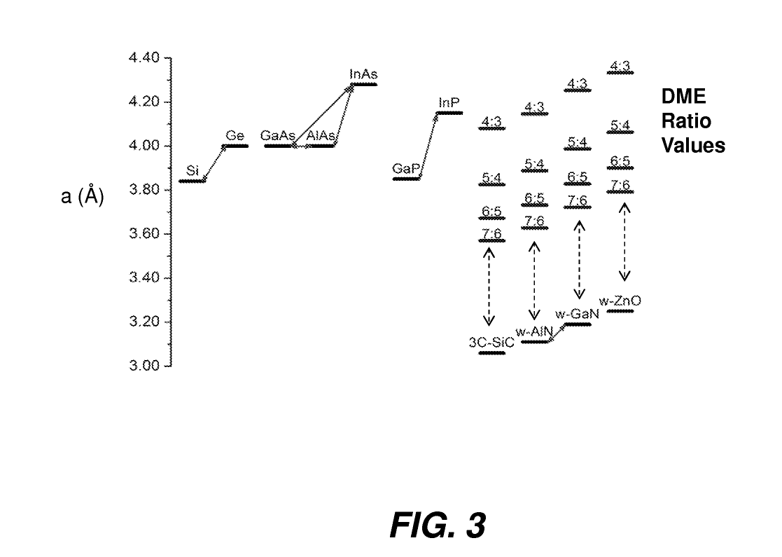

FIG. 3 is a plot of the in-plane lattice spacing “a” (Å) (vertical axis) versus material composition. The solid horizontal lines illustrate the lattice spacings of alloys for the materials shown. For example, Si and Ge can form a continuum of alloys; at 100% Si, the lattice spacing is 3.8 Å and at 100% Ge, the lattice spacing is 4.0 Å. The dotted-line arrows illustrate the growth opportunities using DME, where the DME ratios are illustrated. For example, a 4:3 ratio of SiC can be grown on Ga_{0.2}In_{0.8}P using DME. The tuning of the GaInP composition illustrates LT-DME.

Note that Si—Ge forms a continuous alloy, as do the Ga—Al—N, Ga—Al—As, In—Ga—As, In—Ga—P, and In—Al—As systems. FIG. 3 indicates that there is a relatively large (˜20%) lattice mismatch between Si wafer 10 and materials 22 SiC and Ga—Al—N. However, long-range order can still be achieved by matching integral numbers of lattice spacings “a” using DME. In DME, substrate 10 is usually heated between room temperature and 700° C. Also, substrate 10 and deposited material 22 are usually annealed after the deposition up to 700° C. for up to about 30 minutes. The elevated temperature either during or post deposition is to provide the deposited species 22 with sufficient surface energy to rearrange and orient themselves with the crystalline substrate 10. Some deposition methods provide the deposited materials with more energy and thus require less (or no) thermal processing either during or after deposition.

DME has been shown to allow the epitaxial growth of one layer of material having a first lattice constant (a₁) upon which is deposited a different layer of material having a different (second) lattice constant (a₂) by matching an integral number of the first and second lattice constants. For example, AlN has a lattice constant of a₂=3.11 Å, and Si has a lattice constant of a₁=3.84 Å. Fortuitously, 5 lattice spacings of AlN is close to 4 lattice spacings of Si. Specifically, (5)·(3.11)=15.55 Å, and (4)·(3.84)=15.36 Å. The difference is only 0.19 Å (out of 15.5 Å) or 1.2%. This is close enough to allow for epitaxial growth of AlN film 20 on a Si wafer 10. Other examples of DME include: Growing In₂O₃ on Al₂O₃; Growing NdNiO₃ on Si (100); Growing ZnO on Y₂O₃; Growing GaN on SiGe (30% Ge); and Growing SiC on Si.

It is known in the art that DME works best for some materials when the multiple of one lattice spacing a₁ is within 7% of the multiple of the second lattice spacing a₂, i.e., the the lattice mismatch is within 7%. It has been found that DME works better when the lattice mismatch is smaller, e.g., 2% or 1%. The smaller the mismatch, the better the growth of the second layer because fewer dislocation defects are generated. Ideally, one would want a perfect lattice match to grow layers with the fewest defects.

In an example, a general DME criterion is that m·a₁=n·a₂ to within a threshold value TH. For some materials, the threshold value TH may be as large as 7%, but these materials typically grow with many dislocation defects. Better growth conditions occur when the DME criterion is matched to within 2%, or within 1% or is essentially perfect (i.e., the lattice mismatch is substantially zero, or TH=0). While this represents a tremendous improvement in expanding the number of materials that can be epitaxially grown, it still does not allow for arbitrary materials to be grown. Furthermore, the ubiquity of Si wafers makes it commercially desirable to have the starting substrate 10 be a Si wafer. For an Si wafer 10, the conventional DME process is limited to materials whose lattice constants satisfy the above threshold condition for Si wafer 10.

### Lattice-Tuned DME (LT-DME)

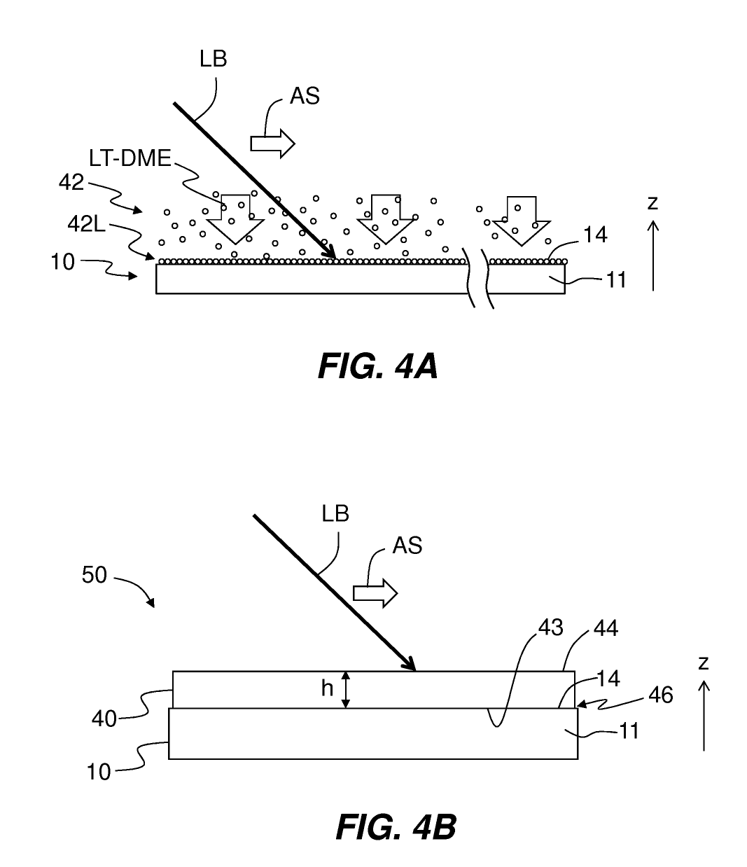

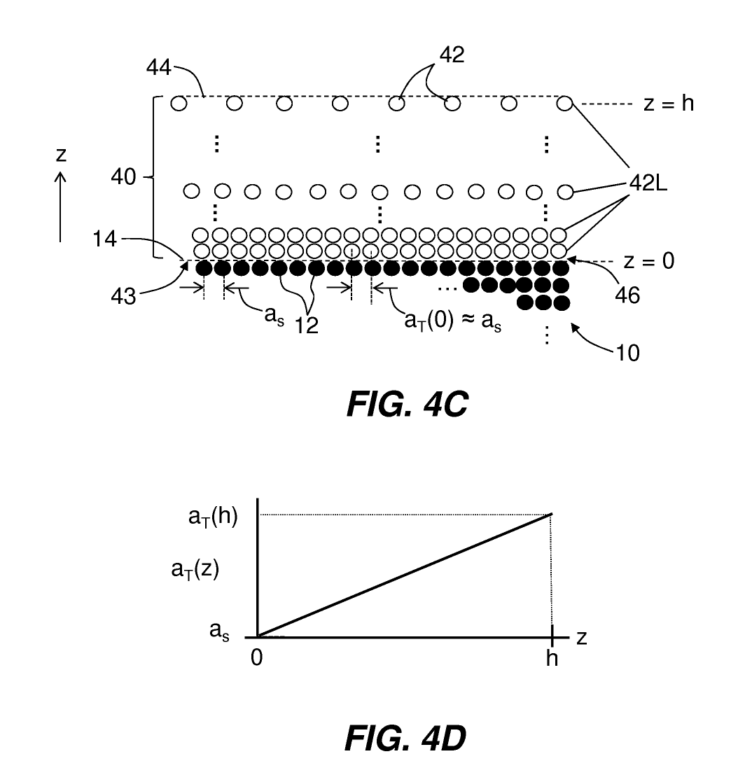

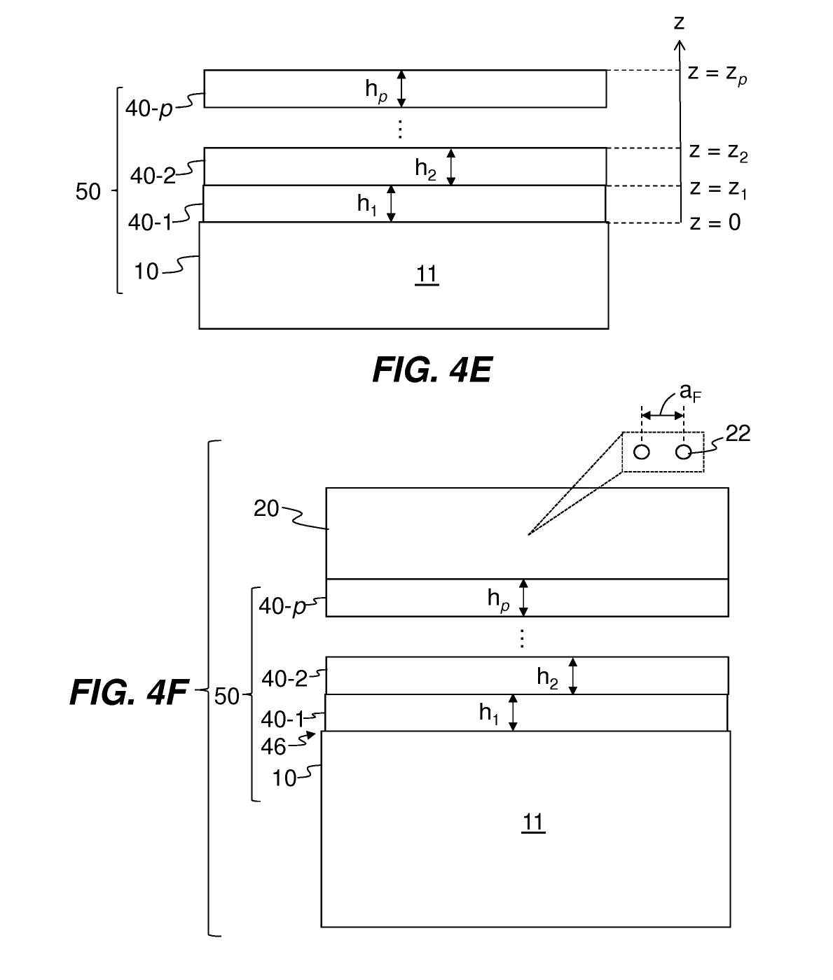

An aspect of the disclosure involves employing a modified version of DME referred to herein as “Lattice-Tuned DME” or LT-DME. FIGS. 4A through 4F illustrate an example LT-DME process performed using substrate 10 to form a transition layer 40 using a species 42 that forms layers 42L.

LT-DME is the heteroepitaxial growth of the transition layer 40 on substrate 10, where at least one of the materials (film or substrate) belongs to a continuous alloy system. The stoichiometry of the alloy is chosen to tune the lattice spacing of transition layer 40 so that the lattice spacings of the transition layer and substrate 40 substantially satisfy a first lattice-matching condition m:n to with a threshold value TH, which has a maximum of 7%. This includes the special case where the ratio is 1:1 and the lattice spacings are equal.

With a continuum of lattice spacing provided by the continuous alloy system, the lattice spacing of transition layer 40 can be varied to provide a second lattice-matching condition of i:j (to within the lattice mismatch threshold TH) to a final film 20 to be formed atop the transition layer. Thus, the number of possible materials that can be grown using DME to form final film 20 is greatly enhanced. In example, the first and second lattice mismatch conditions (as defined by threshold TH) are within 7% or within 2%, or within 1%, or substantially 0% (i.e., no lattice mismatch). In an example embodiment, the first lattice mismatch condition can be different from the second lattice mismatch condition.

Thus, the composition of species 42 is varied during the LT-DME process so that the transition layer 40 has varying alloy composition as defined by layers 42L. Some layers 42L can have the same composition, but not all of layers 42 have the same composition. The transition layer 40 resides between substrate 10 and a desired final film 20 (see FIG. 4F), wherein the substrate and the desired film have different lattice spacings that generally preclude performing conventional DME to form the final film directly on the substrate surface. The LT-DME process allows for the initial composition of the alloy of layers 42L of transition layer 40 to be chosen to LT-DME match the substrate. The stoichiometry is then varied through the thickness of transition layer 40 (e.g., by varying the composition of layers 42L) to achieve a composition that is a LT-DME matched to the final layer 20.

In an example, transition layer 40 has a continuously varying stoichiometry, i.e., the layers 42L vary continuously in their stoichiometry from substrate 10 to final film 20. However, any reasonable variation in stoichiometry for layers 42L can be employed that results in an LT-DME match to the final layer 20.

FIG. 4A shows an example whereby a laser beam LB is used to process layers 42L as they are being deposited using LT-DME, which is indicated by the large arrows, and as described in greater detail below. FIG. 4B is a cross-sectional view of an example template substrate 50 formed from Si wafer 10 as the starting substrate. The template substrate 50 includes at least one transition layer 40 formed on upper surface 14 of Si wafer 10. FIG. 4B also shows an example whereby transition layer 40 is optionally annealed by laser beam LB after the transition layer is deposited. Arrow AS shows a direction in which laser beam LB is scanned.

In an example, the laser processing includes a laser annealing process, such as laser-assisted atomic-layer deposition (LA-ALD). Example LA-ALD systems and methods suitable for use in the methods disclosed herein are disclosed in U.S. Patent Application Ser. No. 61/881,369, filed on Sep. 22, 2013, and entitled “Method and apparatus for forming device quality gallium nitride layers on silicon substrates.” Laser processing of transition layer 40 can be used to improve the crystallographic alignment between surface 12 of Si wafer 10 and the transition layer.

FIG. 4C is a close-up view of an example transition layer 40 being formed atop upper surface 14 of Si wafer 10 with layers 42L of material 42, as shown in FIG. 4A. Substrate 10 is shown with atoms 12 that define upper surface 14 of the substrate and that have a substrate lattice spacing aₛ.

Transition layer 40 has a lower surface 43, and an upper surface 44. Lower surface 43 interfaces with upper surface 14 of Si wafer 10 and defines a wafer-layer interface 46. Transition layer 40 has a height (thickness) h and a varying (e.g., graded) structure that defines a lattice spacing a_{T} that varies in the z-direction, e.g., from z=0 at lower surface 43 to z=h at upper surface 44. Though the variation of a_{T} with z is discrete with layers 42L, the variable lattice spacing of transition layer 40 is denoted a_{T}(z) for convenience.

A transition layer 40 can be created in substrate 10 by ion-implantation and annealing. For example, Ge can be implanted into an Si substrate 10, and through annealing, a transition layer of SiGe can be produced. The percentage of Ge is determined by the dopant density. This can produce a variety of lattice spacings, and be used to grow additional transition layers 40.

In an example embodiment, the varying lattice spacing a_{T}(z) of transition layer 40 is formed by varying the mixture of elements that constitute species (material) 42 as the material is deposited as layers 42L. FIG. 4D is an idealized plot of an example linear variation in the lattice spacing a_{T}(z) that can be formed in LT-DME transition layer 40. The layer 42L at wafer-layer interface 46 has lattice spacing a_{T}(0) that substantially matches the lattice spacing aₛ of the substrate wafer 10 (i.e., to within the first lattice mismatch condition). In this example, the lattice spacing a_{T} of the transition increases from the initial value aₛ(0)=aₛ to a final value a_{T}(h). The process works equally well for the case where the lattice spacing decreases from its initial value to its final value.

With reference again to FIG. 4C, the next layer or layers 42L are formed by changing the mixture of elements that constitute material 42 so that the lattice spacing a_{T}(z) changes, e.g., gets larger in the present example. Note that one or more layers 42L can having the same lattice spacing a_{T}(z) when building up transition layer 40. This growth process is continued until a desired lattice spacing a_{T}(h) is obtained at upper surface 44 of transition layer 40. The lattice spacing a_{T}(h) at upper surface 44 is also called the “surface lattice spacing.”

By way of example, transition layer 40 can be formed by combining the elements Si and Ge to form the single-crystal material 42 called silicon-germanium, which is an alloy and is denoted Si₁₋ₓGeₓ. The Ge can be introduced into Si from 0% (x=0) all the way up to 100% (x=1). The result is a continuum of lattice spacings a_{T}(z) in transition layer 40 that range from the original Si wafer lattice spacing aₛ=3.84 Å (at z=0) up to a maximum of 4.00 Å (e.g., a_{T}(h), or the surface lattice spacing), which is the lattice spacing for crystalline Ge. In another example, aluminum nitride (AlN) can be combined with gallium nitride (GaN) to produce an alloy having a continuum of lattice spacings a_{T}(z) from 3.11 Å for AlN to 3.19 Å for GaN.

FIG. 4E is similar to FIG. 4B and illustrates an example embodiment wherein template substrate 50 includes starting substrate 10 and multiple (p) transition layers 40, e.g., layers 40-1, 40-2 . . . 40-p, having respective thicknesses h₁, h₂, . . . hₚ and respective lattice spacings a_{T1}(z), a_{T2}(z), . . . a_{Tp}(z). Examples of such template substrates are discussed below. FIG. 4F is similar to FIG. 4E and shows the final film 20 formed atop the uppermost transition layer 40-p. Also shown in FIG. 4F is the lattice spacing a_{F} of final film 20.

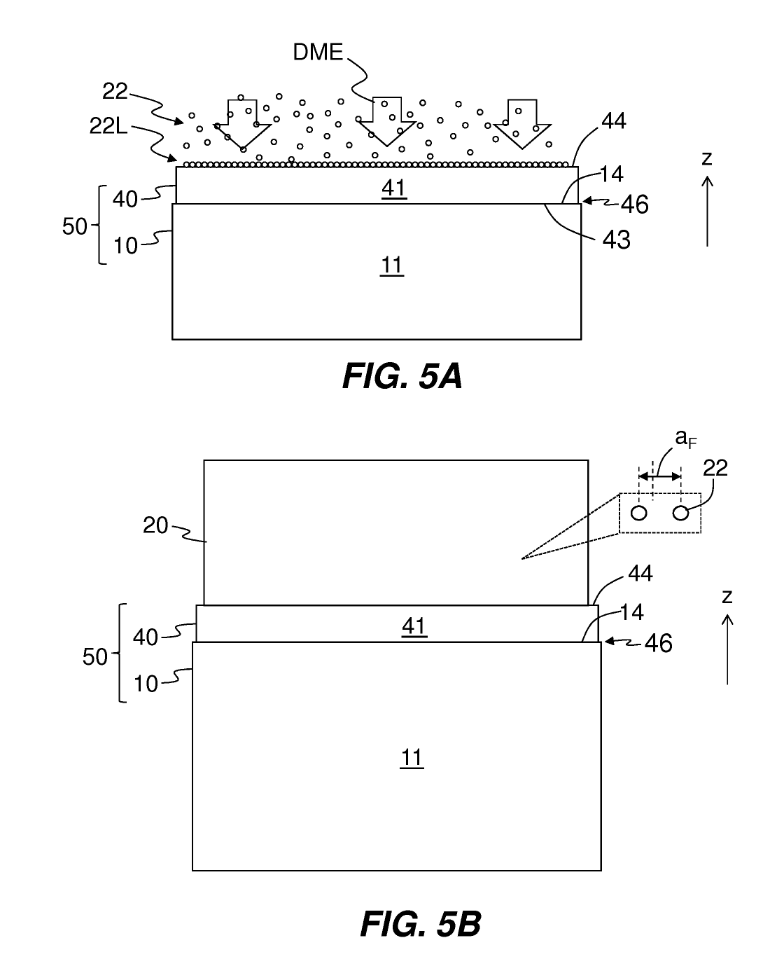

With reference to FIGS. 5A and 5B, once template substrate 50 is formed, it can be used to grow desired final film layer 20 (e.g., using LT-DME, as indicated by the dotted arrows in FIG. 3) having the final lattice spacing a_{F}. It is noted again that final film 20 could not, for all practical purposes, be grown directly on Si wafer surface 12 due to the size of the lattice mismatch between aₛ and a_{F}. The final lattice spacing a_{F} of desired film layer 20 substantially matches the surface lattice spacing a_{Tp}(h) of the upper most transition layer 40-p (i.e., to within the second lattice mismatch condition).

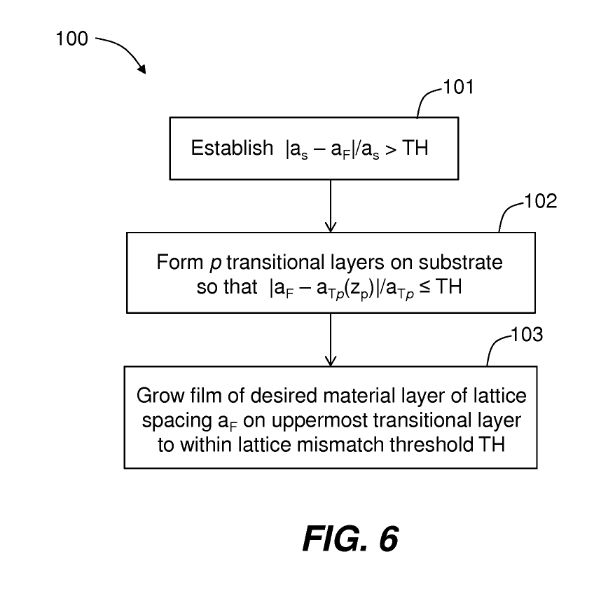

FIG. 6 is a flow diagram 100 that summarizes an example embodiment of a method of forming a desired film 20 that cannot otherwise be formed directly on substrate 10, such as silicon wafer. In step 101, it is established that the final substrate spacing a_{F} of the desired film 20 differs from the substrate lattice spacing aₛ by more than a threshold value. The threshold value TH is usually material dependent, and as noted above is typically around 7% or in some cases 2% The threshold criterion for the tolerance on the lattice mismatch can be summarized by the relation |aₛ−a_{F}|/aₛ≦TH, where “|x|” stands for “the absolute value of x.”

Thus, in step 101, the criterion |aₛ−a_{F}|/aₛ>TH is first established to confirm that the desired final film 20 cannot, for all practical purposes, be formed direction on substrate 10. Reducing the lattice mismatch by lattice tuning to be below a select threshold value TH (e.g., 7% or 2% or 1% or substantially 0%) greatly improves the growth using DME. In an example, a goal of the LT-DME process is to reduce the lattice mismatch between transition layer 40 and the final film 20 by as much as possible.

Step 102 involves using substrate 10 as a starting substrate to form template substrate 50 having p transition layers 40 (i.e., transition layers 40-1, 40-2, . . . 40-p for p=1, 2, 3, . . . ) so that the threshold-based criterion can be satisfied, i.e., |a_{F}−a_{Tp}(zₚ)|/a_{Tp}≦TH where a_{Tp}(zₚ) is the surface lattice spacing of the uppermost transition layer, whose surface resides at z=zₚ (see FIG. 4E). As noted above, in examples, the threshold TH (which indicates the degree of lattice mismatch) is 7% or 2% or 1% or substantially 0%.

Then step 103 involves growing film 20 of the desired material layer 22 on the uppermost transition layer 40-p while remaining within the lattice mismatch threshold TH (i.e., satisfying the second lattice mismatch condition; see FIG. 4F).

With reference again to FIG. 3, certain horizontal lines include ratios m:n (e.g., 4:3) that correspond to the lattice spacing that satisfies the integral matching criterion for the material below, as indicated by the double-ended dashed-line arrows. The lattice spacings of various elements and compounds are shown as dark lines, and their continuous alloys are shown as dark-line arrows. A DME process can be employed using the m:n ratios as shown. For example, AlN can be grown on a SiGe alloy (30% Ge) using a 5:4 ratio (m=5 GaN lattice spacings matching up with n=4 SiGe lattice spacings).

Lattice matching of the Ga—Al—N system to Si can also be performed. The best integral match is the 5:4 ratio for AlN at a₁=3.90 Å, which is 1.6% larger than the Si spacing of aₛ=3.84 Å. However, this lattice-spacing mismatch can be eliminated by forming a transition layer 40 by alloying the Si with 30% Ge, thereby producing a nearly perfect lattice spacing match. The lattice spacing of the alloys Si—Ge varies fairly linearly across the Si—Ge composition range. By implanting Ge into Si and then annealing, template substrate 50 can be provided with a first transition layer 40-1 having a lattice spacing a_{T1}(z=h1) tuned to have a perfect match to the AlN heterolayer. The second transition layer begins with AlN and then the stoichiometry GaₓAl₁₋ₓAs is varied to arrive at any particular composition, having a lattice spacing a_{T2}(z=h2), which can serve as a growth surface for a third transition layer or the desired film layer 20 (see FIG. 4E). For example, let the final composition of the second transition layer be GaN with a lattice spacing of 3.99 A. This can be the growth surface for growing a final heterolayer of GaN or GaAs (a=4.00 Å).

Thus, the methods disclosed herein include forming a sequence of transition layers 40 that allow for the formation of a template substrate 50 that can have an enormous range of available lattice spacings to choose from. The use of multiple transition layers 40 allows for the range of lattice spacings to be gradually varied until the uppermost transition layer has a surface lattice spacing that is sufficiently matched to the final desired lattice spacing a_{F} of the material for the desired film 20.

There are a number of different alloys that can be effectively employed in forming one or more transition layers 40, including SiₓGe₁₋ₓ, GaₓAl₁₋ₓAs, InₓGa₁₋ₓAs, InₓAl₁₋ₓAs, and ZnO. The compound ZnO has a lattice spacing of a=3.252 Å. Normally, ZnO, cannot be grown on Si wafer 10 because the lattice mismatch is nearly 17%. However LT-DME provides a pathway for growing a ZnO film 20. For example, ZnO can match a Si—Ge crystal (with 30% Ge) via the relationship (m=6)·(3.252 Å)≈(n=5)·(3.9 Å). This indicates that a LT-DME process with a m=6 lattice spacing pairing up with a n=5 lattice spacing can be employed. It is emphasized that ZnO could not, for all practical purposes, be grown directly on the surface 12 of Si substrate 10 because the lattice-size mismatch is too large.

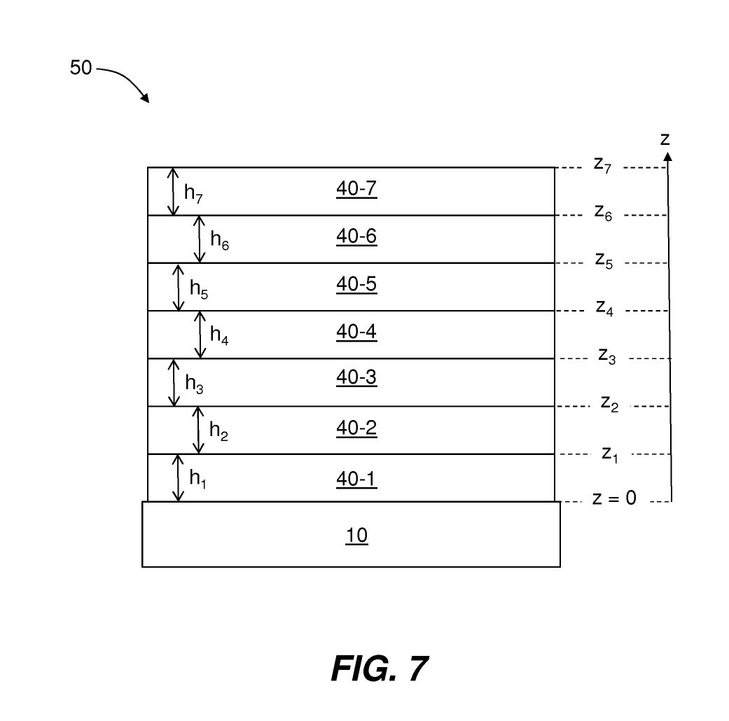

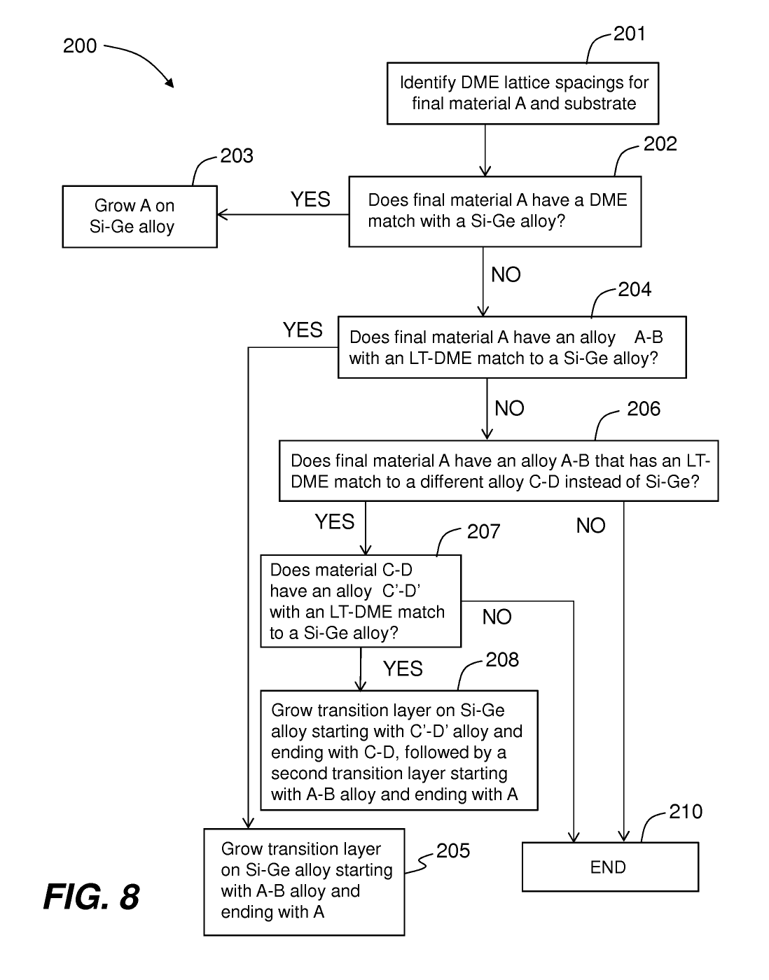

Notice that materials can be combined in many different ways to obtain desirable lattice constants for DME. With reference to FIG. 7, one can start with Si wafer 10 and implant Ge to form a SiGe transitional layer, 40-1 having a concentration of 30% Ge at z=z₁ to define a surface lattice spacing a_{T1}(h₁)≈3.9 Å. AlN can then be grown directly on transitional layer 40-1 with a 5:4 DME ratio to define a transition layer 40-2 having a lattice spacing a_{T2}(z₂)=3.11 Å.

Next, a third transition layer 40-3 with lattice spacing a_{T3}(z) is formed atop the second transition layer 40-2 by blending AlN with GaN to form AlₓGa₁₋ₓN, with a continuing variation of x until pure GaN is grown and defines its own transition layer 40-4.

The upper surface of the GaN transition layer 40-4 has a surface lattice spacing a_{T4}(z₄)=3.19 Å. This surface can then be used to grow any AlₓGa₁₋ₓAs alloy using a 5:4 DME ratio, thereby forming a fifth transition layer 40-5 with a lattice spacing of a_{T5}(z₅)=4.0 Å. If GaAs or AlAs is then grown on the fifth transition layer 40-5, then these materials can form a sixth transition layer 40-6 having a lattice spacing a_{T6}(z) using LT-DME to continuously grade up to InAs and the associated lattice spacing a_{T6}(z₆)=4.28 Å. LT-DME can also be used in the 5:4 ratio to grow on the fifth GaN transition layer a different sixth transition layer 40-6 of In_{0.5}Ga_{0.5}P. Then a seventh transition layer 40-7 grades up to InP with a lattice spacing of a_{T7}(z₇)=4.15 Å or grades down to GaP with a lattice spacing a_{T7}(z₇)=3.85 Å.

In an example, template substrate 50 includes one to ten transition layers 40. In an example where there are two or more transition layers 40, at least one transition layer has a constant lattice size. In an example, the at least one transition layer 40 that has a constant lattice size is formed using LT-DME.

Example methods disclosed herein employ continuous alloy systems of GeₓSi₁₋ₓ, GaₓAl₁₋ₓN, GaₓAl₁₋ₓAs, InₓGa₁₋ₓAs, InₓGa₁₋ₓP, and InₓAl₁₋ₓAs. The use of these alloy systems allows for tuning the lattice spacing of the one or more transition layers 40 of template substrate 50 to an exactly specified value within a large range, and in particular allows for the uppermost transition region 40-p to have a surface lattice spacing a_{Tp}(zₚ) that corresponds to the lattice spacing a_{F} of the desired film 20 to with the second lattice matching condition. The use of LT-DME provides a mechanism for adjusting (tuning) the lattice spacings. Employing LT-DME using one or more continuous alloy systems makes it possible to find a pathway for heteroepitaxial growth of a wide variety of compound semiconductor materials starting with a crystalline substrate 10.

FIG. 8 is a flow diagram 200 that summarizes an example method of growing a desired film 20 of a desired (final) material A having a lattice spacing of a_{F} starting with Si wafer 10. The first step 201 involves identifying the desired material A and the lattice spacings. By way of example, consider the desired final material A has a lattice spacing a_{F}=3.72 Å.

In step 202, the inquiry is made as to whether the material A can be LT-DME matched to a Si—Ge alloy. This includes the special case where the ratio of the lattice spacings is 1:1, that is, the lattice spacings are equal. If the answer is YES, then the method proceeds directly to step 203 wherein a Si—Ge alloy transition layer is used to grow the material. However, the Si—Ge system has a range of lattice spacing aₛ=3.84-4.00 Å, so that a match is not possible and the answer to the inquiry of step 202 for the example is NO.

Since the answer to the inquiry of step 202 was NO, the method proceeds to step 204, which asks: “Is the final material in a system that forms continuous alloys A-B, such that one of the alloys has a LT-DME lattice match with a Si—Ge alloy?” If the answer is YES, then the method proceeds to step 205 wherein the Si—Ge is used to form the first transition layer and the material's alloy A-B can be grown by LT-DME on the Si—Ge. The composition is varied (e.g., continuously graded) to match the lattice spacing of the material A. In this case we assume that the material is not in a system of continuous alloys, so that the answer is No, in which case the method proceeds to step 206. Step 206s asks whether the material A-B can be LT-DME matched to a different material C-D that is in a continuous alloy system. In this case the answer is YES, because GaN has a DME 7:6 lattice spacing of 3.72 Å. The method then proceeds to step 207, which inquires whether the Al—Ga—N alloy system has a LT-DME match to Si—Ge. Indeed, the alloy AlN has a DME 5:4 lattice spacing of 3.89 Å, which matches Si_{0.7}Ge_{0.3}.

Since the answer to query 207 is YES, the method moves to step 208, which involves performing an LT-DME process for growing the material as follows: first grow the Si—Ge transition layer, then deposit a transition layer of Al—Ga—N that varies in composition from pure AlN to pure GaN, and finally deposit the material of interest on the GaN substrate.

Note that in steps 206 and 207, if the answer to the queries is NO, then the there is no suitable match and the method ends in step 210.

It will be apparent to those skilled in the art that various modifications to the preferred embodiments of the disclosure as described herein can be made without departing from the spirit or scope of the disclosure as defined in the appended claims. Thus, the disclosure covers the modifications and variations provided they come within the scope of the appended claims and the equivalents thereto.

What is claimed is:

1. A method of epitaxially growing a desired film having a lattice spacing a_{F} using a crystalline substrate having an upper surface and a lattice spacing aₛ, the method comprising:
forming on the upper surface of the substrate at least one transition layer having a lower surface, an upper surface, a thickness h, and a lattice spacing a_{T}(z) that varies between the lower and upper surfaces such that the lattice spacing a_{T}(0) at the lower surface satisfies m·a_{T}(0)=n·aₛ to within a first lattice mismatch of 7%, where n, m are integers, and the lattice spacing a_{T}(h) at the upper surface satisfies the relationship i·a_{T}(h)=j·a_{F} to within a second lattice mismatch of within 7%, where i, j are integers; and
forming the desired film on the upper surface of the transition layer.

2. The method of claim 1, wherein at least one of first and second lattice mismatches is within 2%.

3. The method of claim 2, wherein at least one of first and second lattice mismatches is within 1%.

4. The method of claim 1, wherein the substrate comprises a material selected from the group of material comprising: Si, Ge, SiGe, AlN, GaN, SiC and diamond.

5. The method of claim 1, wherein substrate comprises Si, and wherein forming the transition layer includes implanting Ge in the Si substrate and then annealing the implanted Ge.

6. The method of claim 1, wherein the substrate comprises an alloy.

7. The method of claim 1, wherein forming the at least one transition layer includes using a deposition process selected from the group of deposition processes comprising: evaporation, sputtering, chemical vapor deposition, metal organic chemical vapor deposition, atomic layer deposition, and laser-assisted atomic layer deposition.

8. The method of claim 1, wherein the at least one transition layer comprises a material selected from the group of materials comprising: GeₓSi₁₋ₓ, GaₓAl₁₋ₓN, GaₓAl₁₋ₓAs, InₓGa₁₋ₓAs, InₓGa₁₋ₓP, and InₓAl₁₋ₓAs.

9. The method of claim 1, wherein the substrate and at least one transition layer have a crystallographic alignment, and further comprising improving the crystallographic alignment by laser processing the at least one transition layer.

10. The method of claim 1, further comprising laser processing the at least one transition layer during said forming of the at least one transition layer.

11. The method of claim 1 comprising multiple transition layers, wherein at least one transition layer has a constant lattice spacing.

12. The method of claim 1, wherein forming the at least one transition layer includes performing domain matching epitaxy.

13. The method of claim 1, wherein forming the at least one transition layer includes performing lattice-tuned domain matching epitaxy.

14. The method of claim 1, wherein forming the at least one transition layer includes forming one to ten transition layers.

15. The method of claim 1, wherein the substrate is heated during the forming of the at least one transition layer.

16. A method of forming a template substrate for growing a desired film having a lattice spacing a_{F}, the method comprising:
forming on an upper surface of a crystalline substrate having a lattice spacing aₛ at least one transition layer having a lower surface, an upper surface, a thickness h, and a lattice spacing a_{T}(z) that varies between the lower and upper surfaces of the at least one transition layer such that the lattice spacing a_{T}(0) at the lower surface satisfies the relationship m·a_{T}(0)=n·aₛ to within a first lattice mismatch of 7%, where n, m are integers, and the lattice spacing a_{T}(h) at the upper surface of the at least one transition layer satisfies the relationship i·a_{T}(h)=j·a_{F} to within a second lattice mismatch of 7%, where i, j are integers.

17. The method of claim 16, wherein at least one of first and second lattice mismatches is within 2%.

18. The method of claim 17, wherein at least one of first and second lattice mismatches is within 1%.

19. The method of claim 16, where the crystalline substrate comprises a material selected from the group of materials comprising: Si, Ge, SiGe, AlN, GaN, SiC and diamond.

20. The method of claim 16, wherein forming the at least one transition layer includes using a deposition process selected from the group of deposition processes comprising: evaporation, sputtering, chemical vapor deposition, metal organic chemical vapor deposition, atomic layer deposition, and laser-assisted atomic layer deposition.

21. The method of claim 16, wherein the at least one transition layer comprises a material selected from the group of materials comprising: GeₓSi₁₋ₓ, GaₓAl₁₋ₓN, GaₓAl₁₋ₓAs, InₓGa₁₋ₓAs, InₓGa₁₋ₓP, InₓAl₁₋ₓAs and ZnO.

22. The method of claim 16, wherein the substrate and at least one transition layer have a crystallographic alignment, and further comprising improving the crystallographic alignment by laser processing the at least one transition layer.

23. The method of claim 16, further comprising laser processing the at least one transition layer during said forming of the at least one transition layer.

24. The method of claim 16, comprising multiple transition layers, wherein at least one of the transition layers has a constant lattice spacing.

25. The method of claim 16, wherein forming the at least one transition layer includes performing domain matching epitaxy.

26. The method of claim 16, wherein forming the at least one transition layer includes performing lattice-tuned domain matching epitaxy.

27. The method of claim 16, wherein forming the at least one transition layer includes forming one to ten transition layers.

28. The method of claim 16, wherein the substrate is heated during the forming of the at least one transition layer.

29. The method of claim 16, further comprising forming the desired film on the upper surface of the transition layer.

30. A method of epitaxially growing a final film using a crystalline substrate having a surface and a substrate lattice spacing, the method comprising:
forming on the substrate surface at least one transition layer having a lattice spacing that varies between the lower and upper surfaces such that the lattice spacing at the lower surface matches the substrate lattice spacing to within a first lattice mismatch of 7% and the lattice spacing at the upper surface matches a lattice spacing of the final film to within a second lattice mismatch of 7%; and
forming the final film on the upper surface of the transition layer.

31. The method of claim 30, wherein at least one of first and second lattice mismatches is within 2%.

32. The method of claim 31, wherein at least one of first and second lattice mismatches is within 1%.

33. The method of claim 30, wherein the substrate comprises a material selected from the group of material comprising: Si, Ge, SiGe, AlN, GaN, SiC and diamond.

34. The method of claim 30, wherein substrate comprises Si, and wherein forming the transition layer includes implanting Ge in the Si substrate and then annealing the implanted Ge.

35. The method of claim 30, wherein the substrate comprises an alloy.

36. The method of claim 30, wherein forming the at least one transition layer includes using a deposition process selected from the group of deposition processes comprising: evaporation, sputtering, chemical vapor deposition, metal organic chemical vapor deposition, atomic layer deposition, and laser-assisted atomic layer deposition.

37. The method of claim 30, wherein the at least one transition layer comprises a material selected from the group of materials comprising: GeₓSi₁₋ₓ, GaₓAl₁₋ₓN, GaₓAl₁₋ₓAs, InₓGa₁₋ₓAs, InₓGa₁₋ₓP, and InₓAl₁₋ₓAs.

38. The method of claim 30, wherein the substrate and at least one transition layer have a crystallographic alignment, and further comprising improving the crystallographic alignment by laser processing the at least one transition layer.

39. The method of claim 30, further comprising laser processing the at least one transition layer during said forming of the at least one transition layer.

40. The method of claim 30, comprising multiple transition layers, wherein at least one transition layer has a constant lattice spacing.

41. The method of claim 30, wherein forming the at least one transition layer includes performing domain matching epitaxy.

42. The method of claim 30, wherein forming the at least one transition layer includes performing lattice-tuned domain matching epitaxy.

43. The method of claim 30, wherein forming the at least one transition layer includes forming one to ten transition layers.

44. The method of claim 30, wherein the substrate is heated during the forming of the at least one transition layer.
